(19) United States
(12) Patent Application Publication
(10) Pub. No.: US 2010/0300739 A1
(43) Pub. Date: Dec. 2, 2010

(54) ELECTRONIC APPARATUS AND REINFORCING COMPONENT

(75) Inventor: Kenji SUZUKI, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/772,534

(22) Filed: May 3, 2010

(30) Foreign Application Priority Data
Jun. 2, 2009 (JP) 2009-133156

(51) Int. Cl. H05K 1/18

(52) U.S. Cl. 174/260

(57) ABSTRACT

An electronic apparatus includes a substrate including a wire, an electronic component and a reinforcing component. The electronic component includes a plate-like external shape including a corner at an outer periphery, where the electronic component is mounted on the substrate and connected with the wire at a surface of the electronic component that faces the substrate. The reinforcing component includes a rigidity higher than a rigidity of the substrate, the reinforcing component includes a frame fixed to the substrate at a position where the frame surrounds the electronic component and a pressing portion that projects inward from the frame and that presses at least the corner of the electronic component against the substrate.

### CROSS-REFERENCE TO RELATED APPLICATIONS

This application is based upon and claims the benefit of priority from the prior Japanese Patent Application No. 2009-133156 filed on Jun. 2, 2009, the entire contents of which are incorporated herein by reference.

### FIELD

Various embodiments described herein relate to an electronic apparatus including a substrate on which an electronic component is mounted and to a reinforcing component that ensures a mounting strength of the electronic component mounted on the substrate.

### BACKGROUND

Highly portable electronic apparatuses, such as notebook personal computers, have recently come into widespread use. Many such electronic apparatuses include substrates on which electronic components are mounted. Such an electronic apparatus is generally structured such that a load is frequently applied to the substrate, owing to an external force applied when, for example, the electronic apparatus is carried. If the substrate bends in response to the load, cracks easily occur in welding portions which electrically connect the electronic component to the substrate and with which the electronic component is fixed to the substrate. In addition, there is a risk that the electronic component will be separated from the substrate.

For example, Japanese Patent No. 3001005 and Japanese Unexamined Patent Application Publication No. 7-66335 discusses a process of mounting an electronic component on a substrate while pressing the electronic component with a metal plate that absorbs heat generated by the electronic component and ensures the ground connection. According to this technique, since the electronic component is pressed against the substrate by the metal plate, the electronic component is protected from the substrate that bends as described above, so that formation of cracks in the welding portions and separation of the electronic component from the substrate may be suppressed.

Recently, in electronic components used in electronic apparatuses, such as notebook personal computers, a pin density has been increased and the size of each pin has been reduced in accordance with the reduction in the size of the electronic apparatuses and increase in the number of pins. As a result, the possibility that the formation of cracks in the welding portions or the separation of the electronic component from the substrate will occur in response to bending of the substrate has increased.

### SUMMARY

According to an embodiment, an electronic apparatus includes a substrate including a wire, an electronic component and a reinforcing component. The electronic component includes a plate-like external shape including a corner at an outer periphery, where the electronic component is mounted on the substrate and connected with the wire at a surface of the electronic component that faces the substrate. The reinforcing component includes a rigidity higher than a rigidity of the substrate, the reinforcing component includes a frame fixed to the substrate at a position that surrounds the electronic component and a pressing portion that projects inward from the frame and that presses at least the corner of the electronic component against the substrate.

An object and advantages of the various embodiments will be realized and attained by means of the elements and combinations particularly pointed out in the claims. It is to be understood that both the foregoing general description and the following detailed description are exemplary and explanatory and are not restrictive of the various embodiments, as claimed.

Additional aspects and/or advantages will be set forth in part in the description which follows and, in part, will be apparent from the description, or may be learned by practice of the various embodiments.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 illustrates an external view of a notebook personal computer as an example of an electronic apparatus;

FIG. 2 illustrates a main unit in a state in which atop plate is removed so that a circuit substrate disposed in the main unit is exposed;

FIG. 3 illustrates a main unit in a state in which a metal plate is removed so that a CPU is exposed;

FIG. 4 illustrates the main unit in FIG. 1 in a state in which a reinforcing component is removed from the state illustrated in FIG. 3;

FIG. 5 is an enlarged perspective view of a reinforcing component;

FIG. 6 is a perspective view illustrating a manner in which a reinforcing component is fixed to a circuit substrate with screws;

FIG. 7 is a sectional view of FIG. 2 taken along line A-A;

FIG. 8 is a sectional view of FIG. 2 taken along line B-B; and

FIG. 9 illustrates an example of an embodiment.

### DETAILED DESCRIPTION

Reference will now be made in detail to the embodiments, examples of which are illustrated in the accompanying drawings, wherein like reference numerals refer to the like elements throughout. The embodiments are described below to explain the present invention by referring to the figures.

An electronic apparatus and a reinforcing component according to embodiments will now be described with reference to the drawings.

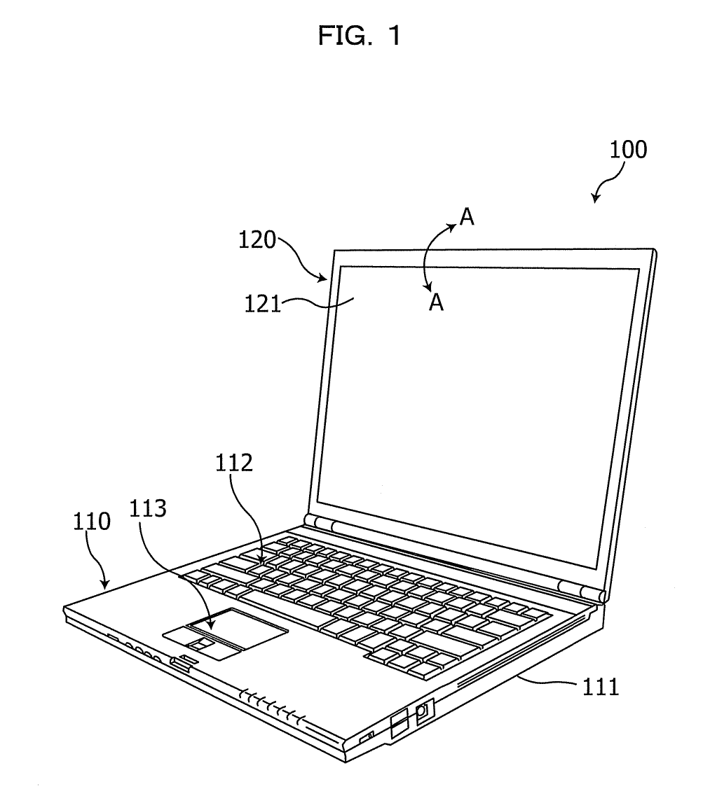

FIG. 1 illustrates an external view of a notebook personal computer (hereinafter referred to as notebook PC) 100 as an example of an electronic apparatus. While a notebook is used herein as an example, the present invention is not limited to any particular type of device.

The notebook PC 100 includes a main unit 110 and a display unit 120. The display unit 120 is connected to the main unit 110 such that the display unit 120 may be opened and closed (adjusted) with respect to the main unit 110 in the directions indicated by arrows A. FIG. 1 illustrates the notebook PC 100 in the state in which the display unit 120 is opened with respect to the main unit 110.

The main unit 110 of the notebook PC 100 includes a main housing 111. Components including a hard disc drive and various substrates are housed in the main housing 111. A keyboard 112 in which a plurality of keys are arranged and a trackpad 113 are provided on a top surface of the main unit 110. The display unit 120 of the notebook PC 100 includes a monitor 121 which displays, for example, a result of information processing performed in the main unit 110.

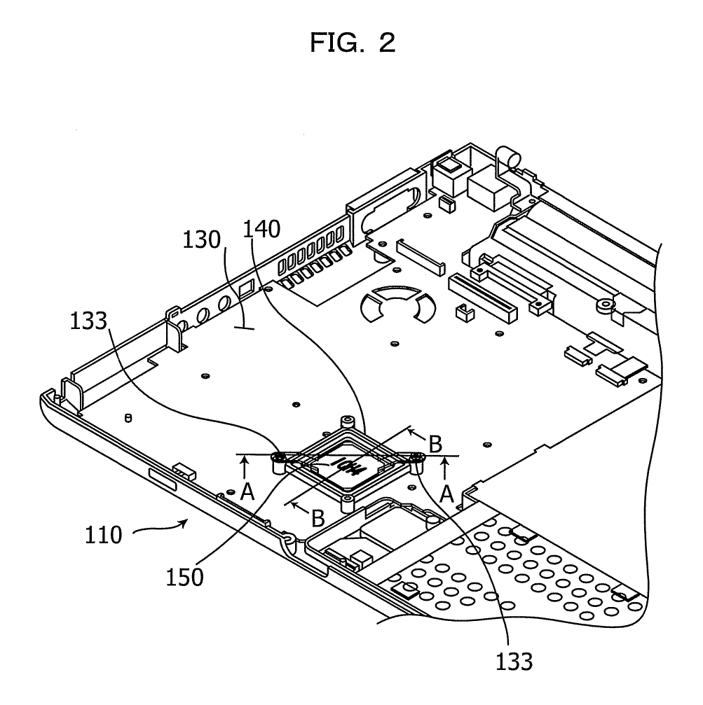

FIG. 2 illustrates the main unit 110 in FIG. 1 in a state in which atop plate is removed so that a circuit substrate 130 disposed in the main unit 110 is exposed.

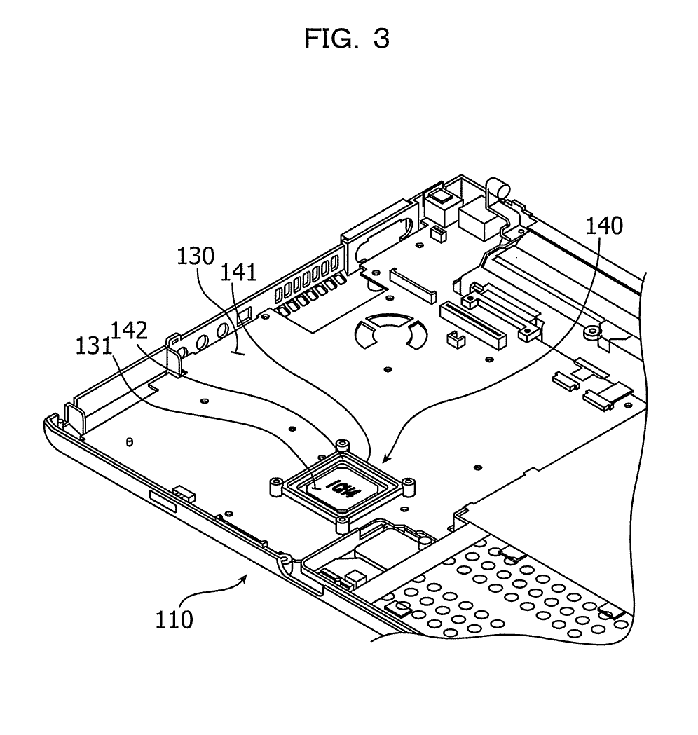

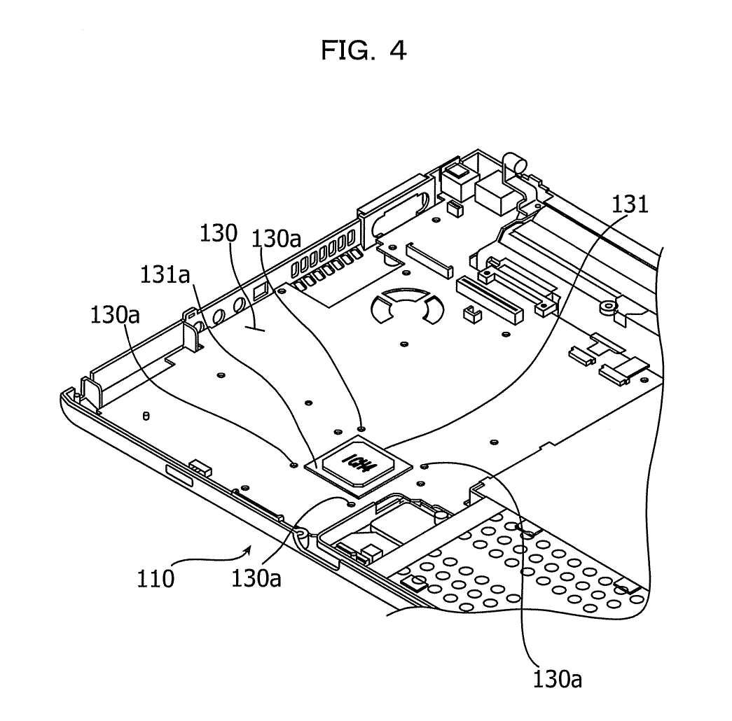

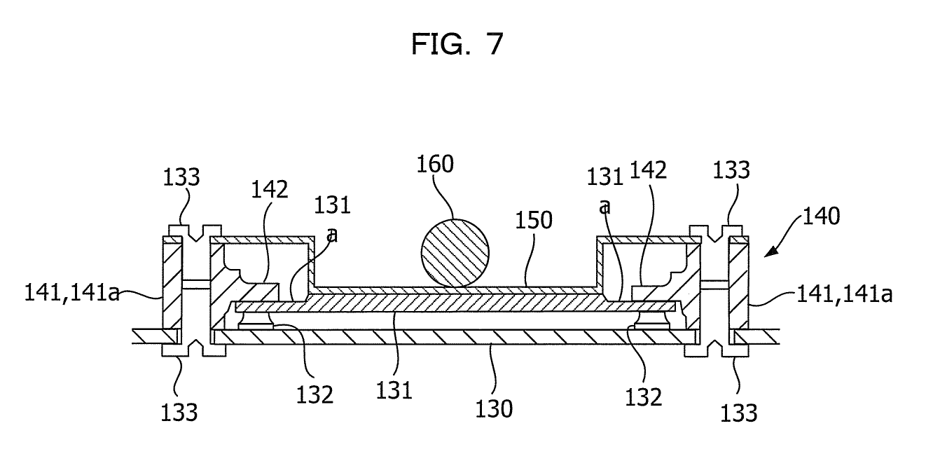

In an embodiment, the circuit substrate 130 includes lands 132 (see description of FIG. 7 below) that provides electrical connection to a CPU 131 (see description of FIGS. 3 and 4 below) that provides the main operation function of the notebook PC 100. Similar to many common semiconductor integrated circuits, the CPU 131 is welded to the lands 132 on the circuit substrate 130, and is thereby mounted on the circuit substrate 130. The CPU 131 has a plate-like external shape, and an outer periphery thereof is substantially square, which is an example of a polygonal shape. One of the front and back surfaces of the CPU 131 is welded onto the lands 132 in accordance with a process of mounting the CPU 131 on the circuit substrate 130. The circuit substrate 130 corresponds to an example of a substrate. The CPU 131 corresponds to an example of an electronic component.

In an embodiment, the CPU 131 is protected by a reinforcing component 140 from the circuit substrate 130 that bends in response to, for example, an external force applied to the notebook PC 100. In an embodiment, the reinforcing component 140 provides a shield from damage including those that may potentially be caused when the circuit substrate 130 is adjusted or moved.

In FIG. 2, electronic components other than the CPU 131 (see FIGS. 3 and 4) provided on the circuit substrate 130 are omitted.

In an embodiment, a metal plate 150 is fixed to the reinforcing component 140 by two screws 133. The metal plate 150 comes into tight contact with the CPU 131 (see FIGS. 3 and 4) and absorbs heat generated by the CPU 131. The metal plate 150 also serves a function of ensuring electromagnetic compatibility (EMC) for the CPU 131 in addition to the function of absorbing heat. Since the function of ensuring the EMC is provided by the metal plate 150, the ground connection is ensured and emission and reception of electromagnetic noise by the CPU 131 may be suppressed.

FIG. 3 illustrates the main unit 110 in FIG. 1 in the state in which the metal plate 150 is removed from the state illustrated in FIG. 2 so that the CPU 131 is exposed. FIG. 4 illustrates the main unit 110 in FIG. 1 in the state in which the reinforcing component 140 is removed from the state illustrated in FIG. 3.

As illustrated in FIG. 4, the CPU 131 according to an embodiment is a chip component having a substantially square plate-like external shape. The CPU 131 includes a flange 131a at an outer periphery thereof. The flange 131a is thinner than a central section of the CPU 131.

As illustrated in FIG. 3, the reinforcing component 140 includes a frame 141 fixed to the circuit substrate 130 at a position where the frame 141 surrounds the CPU 131. In an embodiment, the frame 141 has a rigidity higher than the rigidity of the circuit substrate 130. The reinforcing component 140 includes a pressing portion 142 that projects inward from the frame 141. The pressing portion 142 presses at least corners of the CPU 131 against (towards) the circuit substrate 130. The pressing portion 142 corresponds to an example of a projecting portion.

The frame 141 increases a strength of the circuit substrate 130 in an area where an electronic component (CPU 131 is described as an example herein) is mounted on the circuit substrate 130. The pressing portion 142 strongly presses at least corners of the electronic component (CPU 131) against the circuit substrate 130. The corners of the electronic component (CPU 131) correspond to regions where stress tends to concentrate when the circuit substrate 130 bends. This stress causes formation of cracks in welding portions and separation of the electronic component (CPU 131) from the circuit substrate 130, as described below. The frame 141 and the pressing portion 142 of the reinforcing component 140 together increase the overall strength of the circuit substrate 130 and the electronic component (CPU 131) in the area where the electronic component (CPU 131) is mounted on the circuit substrate 130. Owing to the increase in the overall strength, the electronic component (CPU 131) is strongly protected from the circuit substrate 130 in the bent state. As a result, the formation of cracks in the welding portions and the separation of the electronic component (CPU 131) may be suppressed and avoided.

The reinforcing component 140 will now be described in detail.

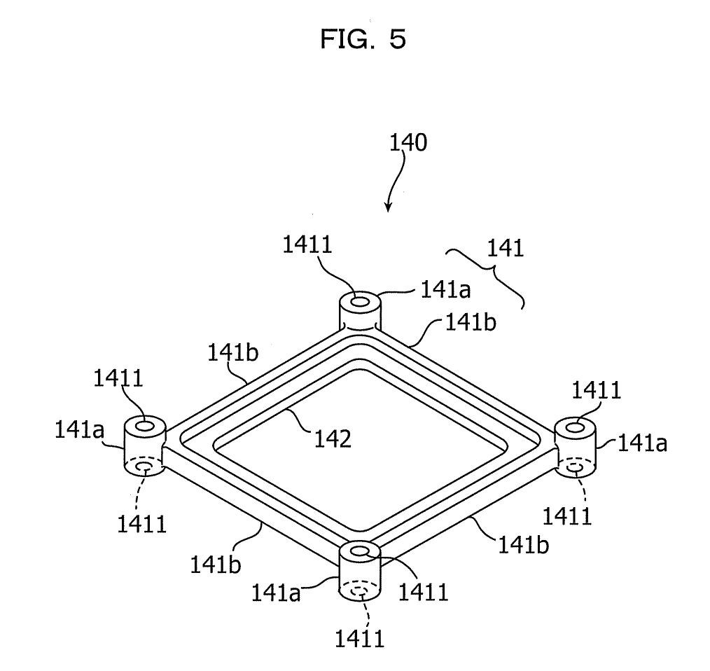

FIG. 5 is an enlarged perspective view of the reinforcing component 140.

As illustrated in FIG. 5, the frame 141 of the reinforcing component 140 includes four columnar portions 141a and four rod-shaped portions 141b. The rod-shaped portions 141b connect the columnar portions 141a to each other. The pressing portion 142 projects inward from an entire inner circumference of the frame 141 including the columnar portions 141a. The portions 141b connect with the columnar portions 141a and form sides of the frame 141.

In an embodiment, the reinforcing component 140 is formed by die casting.

In an embodiment, owing to the above-described structure of the reinforcing component 140, the corners of the CPU 131, where the stress tends to concentrate, are pressed by portions of the pressing portion 142 that project from the columnar portions 141a. Thus, the portions of the pressing portion 142 that project from the columnar portions 141a, which are fixed to the circuit substrate 130, are pressed against the CPU 131. Therefore, the CPU 131 is strongly protected from the circuit substrate 130 in the bent state.

As illustrated in FIG. 4, four through holes 130a are formed in the circuit substrate 130 at positions near the four corners of the CPU 131. The columnar portions 141a are provided with internal threads 1411 for fixing the reinforcing component 140 to the circuit substrate 130 with screws at the bottom ends of the columnar portions 141a.

In an embodiment, the internal threads 1411 are provided at the bottom ends of the columnar portions 141a. Therefore, the reinforcing component 140 is strongly fixed to the circuit substrate 130 by a simple method, that is, with screws.

In the structure of the frame including a plurality of columnar portions and a plurality of rod-shaped portions, the method for fixing the frame or the columnar portions to the substrate is not limited to the method using the screws. For example, a fixing method, such as crimping, other than the method using the screws may be used instead.

In the following description, the concept regarding the circuit substrate 130 is ignored and the structure of the reinforcing component 140 will be mainly considered. In this case, the reinforcing component 140 may be described as follows.

That is, the reinforcing component 140 includes the frame 141, which is described in more detail below, and a projecting portion (pressing portion 142 is described as an example herein). The frame 141 includes a plurality of columnar portions 141a provided with internal threads at one end thereof and rod-shaped portions 141b that connect the columnar portions 141a to each other. The projecting portion (pressing portion 142) projects inward from the frame 141.

When the reinforcing component 140 has the above-described structure, the reinforcing component 140, which provides the overall reinforcement of the circuit substrate 130 and the electronic component (CPU 131), may be easily attached to the circuit substrate 130.

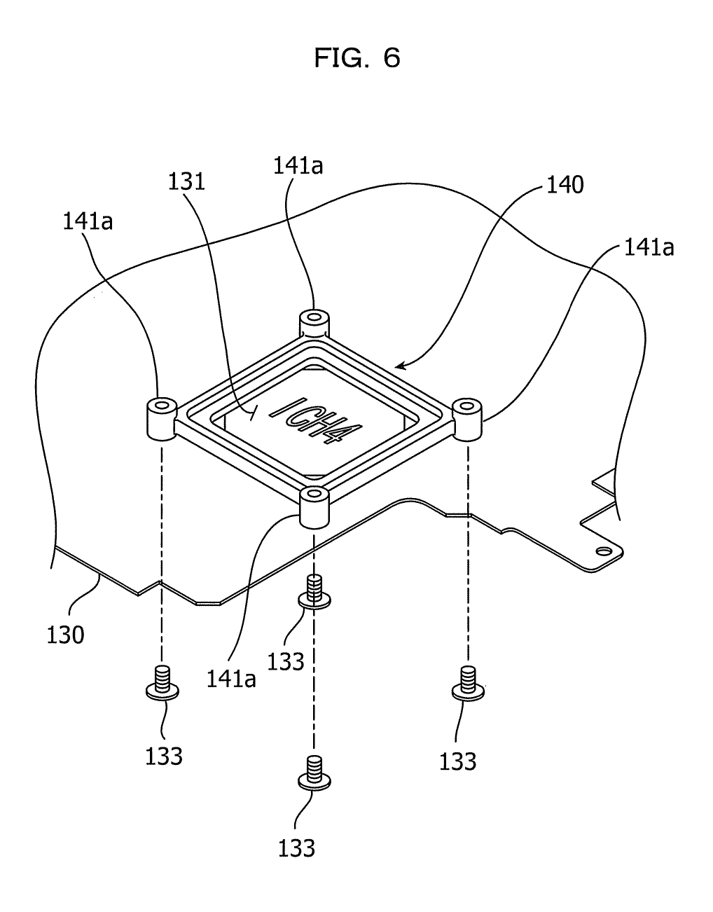

FIG. 6 is a perspective view illustrating the manner in which the reinforcing component 140 is fixed to the circuit substrate 130 with screws.

As illustrated in FIG. 6, first, the reinforcing component 140 is placed on the circuit substrate 130 such that the pressing portion 142 covers the flange 131a at the outer periphery of the CPU 131. Then, four screws 133 are inserted through the four through holes 130a in the circuit substrate 130 and are screwed into the internal threads 1411 at the bottom ends of the columnar portions 141a. Thus, the reinforcing component 140 is fixed to the circuit substrate 130 with the screws 133. As a result, a pressing force is applied by the reinforcing component 140 to the flange 131a at the outer periphery of the CPU 131.

The reinforcing effect provided by the reinforcing component 140 will now be described in detail with reference to a sectional view of FIG. 2 taken along line A-A and a sectional view of FIG. 2 taken along line B-B.

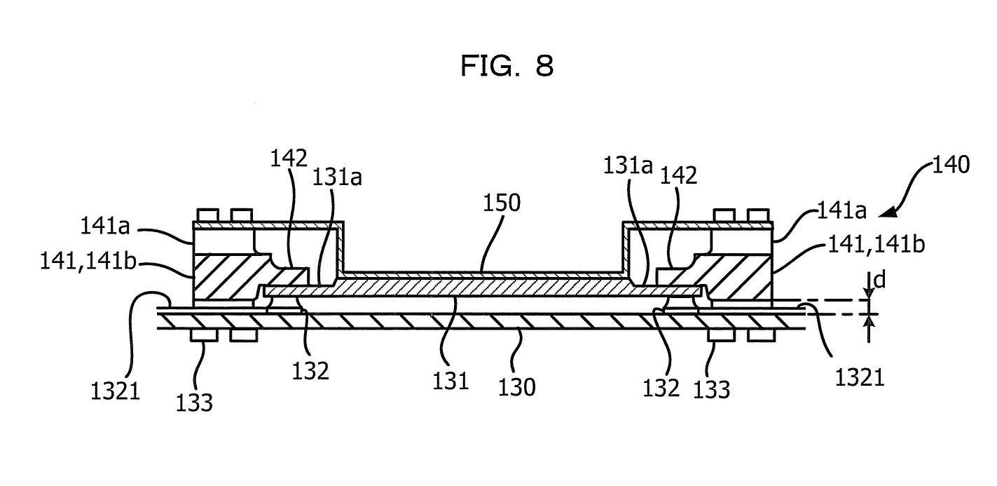

FIG. 7 is a sectional view of FIG. 2 taken along line A-A. FIG. 8 is a sectional view of FIG. 2 taken along line B-B.

In an embodiment, the heat generated by the CPU 131 and absorbed by the metal plate 150 illustrated in FIG. 2 is guided to a radiation component (not illustrated) through a so-called heat pipe. FIG. 7 illustrates a heat pipe 160 used to transfer the heat. However, the heat pipe 160 is omitted in FIGS. 2 and 8.

As described above, the screws 133 inserted through the through holes 130a in the circuit substrate 130 are screwed into the internal threads 1411 provided at the bottom ends of the columnar portions 141a, so that the reinforcing component 140 is fixed to the circuit substrate 130, as illustrated in FIGS. 7 and 8. The frame 141, which includes the columnar portions 141a and the rod-shaped portions 141b, surround the outer peripheral portion of the CPU 131 on the circuit substrate 130. The pressing portion 142 that projects inward from the frame 141 presses the flange 131a at the outer periphery of the CPU 131 against the circuit substrate 130 over the entire circumference of the flange 131a.

A comparative example to be compared with an embodiment will be described before explaining the reinforcing effect provided by the reinforcing component 140.

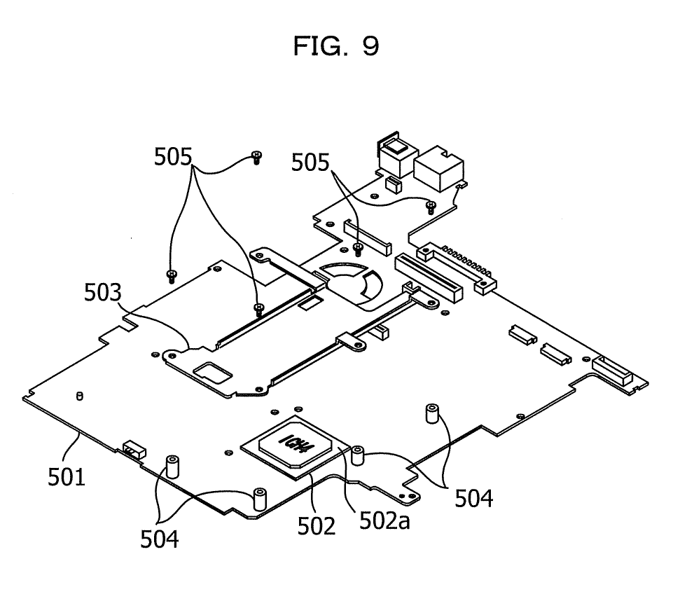

FIG. 9 illustrates the comparative example to be compared with an embodiment.

In the comparative example illustrated in FIG. 9, to diffuse heat generated by a CPU 502 mounted on a circuit substrate 501, a radiation metal plate 503 is fixed to the circuit substrate 501 such that the radiation metal plate 503 is in tight contact with the top surface of the CPU 502. In the comparative example illustrated in FIG. 9, the radiation metal plate 503 is fixed with screws 505 to a plurality of studs 504 provided on the circuit substrate 501.

In the structure of the comparative example illustrated in FIG. 9, the radiation metal plate 503 also serves a function of pressing the CPU 502 against the circuit substrate 501. Therefore, when the circuit substrate 501 bends in response to an external force, formation of cracks in welding portions and separation of the CPU 502 from the circuit substrate 501 may be suppressed by the pressing force applied by the radiation metal plate 503.

Recently, a pin density has been increased and the size of each pin has been reduced in accordance with the reduction in the size of CPUs and increase in the number of pins. As a result, the possibility that the formation of cracks or the separation from the circuit substrate will occur at the welding portions in response to bending of the circuit substrate has increased. In view of such a situation, the pressing force applied by the radiation metal plate 503 in the comparative example illustrated in FIG. 9 to press the CPU 502 against the circuit substrate 501 is relatively weak.

In the CPU 502, which has a rectangular shape, the stress generated when the circuit substrate 501 bends mainly concentrates at the four corners of the CPU 502. This stress serves as a force that tries to separate the CPU 502 from the circuit substrate 501. In the structure of the comparative example illustrated in FIG. 9, the radiation metal plate 503 is not in contact with the flange 502a of the CPU 502, and substantially no pressing force is applied to the flange 502a.

Therefore, in the comparative example illustrated in FIG. 9, it is difficult to suppress the formation of cracks in the welding portions and the separation of the CPU 502 from the circuit substrate 501 when the circuit substrate 501 bends and the stress concentrates at the four corners of the CPU 502.

Unlike the above-described comparative example, according to an embodiment, the CPU 131 may be strongly protected from the circuit substrate 130 in the bent state, owing to the following reinforcing effect provided by the reinforcing component 140.

That is, in an embodiment, the frame 141, which surrounds the outer periphery of the CPU 131 and which has a rigidity higher than the rigidity of the circuit substrate 130, provides a function of increasing the strength of the circuit substrate 130 in a substantially square area in which the CPU 131 is mounted. Accordingly, even when an external force is applied to the notebook PC 100 illustrated in FIG. 1 such that the circuit substrate 130 housed in the notebook PC 100 bends, bending of the circuit substrate 130 may be suppressed by the frame 141 of the reinforcing component 140 in the above-described square area in which the CPU 131 is disposed.

In addition, in an embodiment, the flange 131a at the outer periphery of the CPU 131 is pressed against the circuit substrate 130 by the pressing portion 142 that projects inward from the inner periphery of the reinforcing component 140. Accordingly, when the circuit substrate 130 bends, the four corners of the CPU 131, at which the stress tends to concentrate, are strongly pressed against the circuit substrate 130 by the pressing portion 142. As a result, even when the circuit substrate 130 slightly bends in the above-described square area in which the CPU 131 is disposed, formation of cracks in the welding portions and the separation of the CPU 131 may be suppressed at the four corners of the CPU 131.

In an embodiment, bending of the circuit substrate 130 is suppressed by the frame 141 of the reinforcing component 140. In addition, the CPU 131 is strongly protected from the circuit substrate 130 in the bent state by the pressing force applied to the CPU 131 by the pressing portion 142 of the reinforcing component 140. As a result, the formation of cracks in the welding portions and the separation of the CPU 131 may be suppressed.

In an embodiment, the pressing portion 142 of the reinforcing component 140 evenly presses the flange 131a at the outer periphery of the CPU 131 against the circuit substrate 130 instead of pressing mainly the four corners of the CPU 131 at which the stress tends to concentrate. Owing to this structure, in an embodiment, the CPU 131 is strongly protected from the circuit substrate 130 in the bent state.

In an embodiment, as illustrated in FIGS. 5 and 7, the columnar portions 141a of the frame 141 are provided with the internal threads 1411 not only at the bottom ends thereof but also at the top ends thereof. The internal threads 1411 at the top ends of the columnar portions 141a are used as studs for fixing the metal plate 150 which provides the functions of absorbing heat generated by the CPU 131 and ensuring the EMC. Therefore, dedicated studs for fixing the metal plate 150 may be omitted, so that the space on the circuit substrate 130 may be saved and the component mounting area may be reduced.

In addition, since the heat is absorbed by the metal plate 150 in an embodiment, the CPU 131 may be operated in an improved operation environment.

In an embodiment, the metal plate 150 is in contact with the CPU 131 and covers the top surface of the CPU 131. In an embodiment, this structure provides a countermeasure against static electricity for the CPU 131 and ensures the EMC by blocking the emission of electromagnetic noise from the CPU 131 and electromagnetic noise that approaches the CPU 131.

In an embodiment, as illustrated in FIG. 5, the rod-shaped portions 141b connect the columnar portions 141a to each other at positions separated from the ends of the columnar portions 141a at the side of the circuit substrate 130. Therefore, as illustrated in FIG. 8, in the state in which the reinforcing component 140 is fixed to the circuit substrate 130, a gap d is provided between each of the four rod-shaped portions 141b of the frame 141 and the circuit substrate 130. In addition, in an embodiment, a conductive pattern 1321 that extends from the lands 132 that provide electrical connection to the CPU 131 is formed on the surface of the circuit substrate 130 in an area where the gap d is provided. The conductive pattern 1321 is formed such that the conductive pattern 1321 is not in contact with the rod-shaped portions 141b. Thus, in an embodiment, sections on the surface of the circuit substrate 130 under the rod-shaped portions 141b serve as sections in which the conductive pattern 1321 is disposed.

Although the notebook PC 100 is described above as an example of an electronic apparatus according to an embodiment, the electronic apparatus is not limited to the notebook PC. The electronic apparatus may instead be, for example, a mobile apparatus such as a mobile phone or a mobile information terminal.

In addition, in the above-described embodiment, the pressing portion 142 that projects inward from the frame 141 over the entire inner circumference of the frame 141 and that presses the flange 131 a at the outer periphery of the CPU 131 against the circuit substrate 130 over the entire circumference of the flange 131 a is explained as an example of a pressing portion.

However, the pressing portion is not limited to this, and may instead be structured such that the pressing portion presses an outer peripheral portion of the electronic component, such as the CPU, against the circuit substrate mainly at the corners of the electronic component.

The embodiments can be implemented in computing hardware (computing apparatus) in combination with software, such as (in a non-limiting example) any computer that can store, retrieve, process and/or output data and/or communicate with other computers. The results produced can be displayed on a display of the computing hardware. A program/software implementing the embodiments may be recorded on computer-readable media comprising computer-readable recording media. The program/software implementing the embodiments may also be transmitted over transmission communication media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW. An example of communication media includes a carrier-wave signal.

Further, according to an aspect of the embodiments, any combinations of the described features, functions and/or operations can be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention, the scope of which is defined in the claims and their equivalents.

What is claimed is:

1. An electronic apparatus, comprising:
a substrate including a wire;
an electronic component having a plate-like external shape including a corner at an outer periphery, the electronic component being mounted on the substrate and connected with the wire at a surface of the electronic component that faces the substrate; and
a reinforcing component having a rigidity higher than a rigidity of the substrate, where the reinforcing component includes a frame fixed to the substrate at a position that surrounds the electronic component and a pressing portion that projects inward from the frame and that presses at least the corner of the electronic component against the substrate.

2. The electronic apparatus according to claim 1, wherein the frame includes a plurality of columnar portions fixed to the substrate at first ends of the columnar portions and a plurality of rod-shaped portions that connect the columnar portions to each other, and
wherein the pressing portion projects at least from the columnar portions.

3. The electronic apparatus according to claim 2, wherein the columnar portions are provided with internal threads at the first ends, the internal thread being used to attach the reinforcing component to the substrate with screws.

4. The electronic apparatus according to claim 2, wherein the rod-shaped portions connect the columnar portions with each other at positions separated from the first ends of the columnar portions.

5. The electronic apparatus according to claim 2, wherein at least one of the columnar portions is provided with an internal thread at a second end opposite to the first end.

6. The electronic apparatus according to claim 5, comprising:
a metal plate that is in contact with a surface of the electronic component opposite to the surface that faces the substrate, the metal plate being fixed with a screw to the internal thread at the second end of the at least one of the columnar portions.

7. The electronic apparatus according to claim 1, wherein the pressing portion projects inward from the frame over an entire circumference of the frame.

8. A reinforcing component, comprising:
a frame fixed to a substrate that includes a wire and on which an electronic component is mounted, the frame being fixed to the substrate at a position where the frame surrounds the electronic component and having a rigidity higher than a rigidity of the substrate; and
a pressing portion that projects inward from the frame and that presses at least a corner portion of the electronic component against the substrate when the reinforcing component is mounted on the substrate.

9. A reinforcing component, comprising:
a frame including a plurality of columnar portions provided with internal threads at first ends of the columnar portions and a plurality of rod-shaped portions that connect the columnar portions to each other; and
a projecting portion that projects inward from the frame.

10. The reinforcing component according to claim 9, wherein the projecting portion projects at least from the columnar portions.

11. The reinforcing component according to claim 9, wherein the projecting portion projects inward from the frame over an entire circumference of the frame.
